(19) United States
(12) Patent Application Publication
(10) Pub. No.: US 2020/0098940 A1
(43) Pub. Date: Mar. 26, 2020

(54) ENCAPSULATION MATERIAL AND MODULE STRUCTURE

(71) Applicant: INDUSTRIAL TECHNOLOGY RESEARCH INSTITUTE, Hsinchu (TW)

(72) Inventors: Min-Tsung KUAN, Taichung City (TW); Wen-Hsien WANG, Tainan City (TW); Szu-Lin WANG, Hsinchu City (TW); Wen-Hsien CHOU, Lunbei Township (TW); Wen-Kuei LEE, Puyan Township (TW); Fu-Ming LIN, Zhudong Township (TW); Chorng-Jye HUANG, Hsinchu City (TW)

(73) Assignee: INDUSTRIAL TECHNOLOGY RESEARCH INSTITUTE, Hsinchu (TW)

(21) Appl. No.: 16/201,268

(22) Filed: Nov. 27, 2018

(30) Foreign Application Priority Data
Sep. 20, 2018 (TW) 107133174

(51) Int. Cl. H01L 31/048; H01L 31/055; H01L 31/049; C09K 11/06; C09K 11/02

(52) U.S. Cl. CPC H01L 31/0481; H01L 31/055; H01L 31/049; C09K 2211/1425; C09K 11/02; C09K 2211/1466; C09K 2211/1416; C09K 11/06

(57) ABSTRACT

A module structure includes a front sheet, a back sheet opposite to the front sheet, and a solar cell disposed between the front sheet and the back sheet. A first encapsulation film is disposed between the solar cell and the front sheet, and a second encapsulation film is disposed between the solar cell and the back sheet. The first encapsulation film and the second encapsulation film include an encapsulation material, which includes a resin and a fluorescent molecule. The fluorescent molecule includes a fluorescent group bonded to a polyhedral oligomeric silsesquioxane.

### CROSS REFERENCE TO RELATED APPLICATIONS

The present application is based on, and claims priority from, Taiwan Application Serial Number 107133174, filed on Sep. 20, 2018, the disclosure of which is hereby incorporated by reference herein in its entirety.

### TECHNICAL FIELD

The technical field relates to a module structure of a solar cell, and in particular it relates to a composition of its encapsulation film.

### BACKGROUND

Generally, solar cell modules use two transparent flexible encapsulation films to wrap the cell for protection and to maintain the module's lifespan. The encapsulation film fixes the solar cell, connects the circuit line, and provides insulation protection for the cell. In addition, the cell's performance should overcome the surrounding test even after long-term use through the encapsulation film.

Conventional encapsulation films such as ethylene vinyl acetate copolymer (EVA) have advantages such as low cost and excellent flowability. However, EVA film has poor insulation under high voltage, thereby easily resulting in problems such as leakage current and potential induced degradation. In short, the EVA film needs to be replaced with a novel encapsulation material to overcome the above problems.

### SUMMARY

One embodiment of the disclosure provides an encapsulation material, including a resin and a fluorescent molecule, wherein the fluorescent molecule includes a fluorescent group bonded to a polyhedral oligomeric silsesquioxane.

In some embodiments, the resin and the fluorescent molecule have a weight ratio of 100:0.1 to 100:5.

In some embodiments, the fluorescent molecule has a chemical structure of:

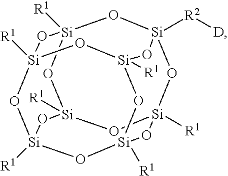

wherein R¹ is linear or branched C₃₋₁₀ alkyl group, wherein R² is —(CₘH₂ₘ)—, —(CₘH₂ₘ—O—CₓH₂ₓ)—, —(CₘH₂ₘ—NR³—CₓH₂ₓ)—, —(CₘH₂ₘ-Ph-CₙH₂ₙ—O—CₓH₂ₓ)—, —(CₘH₂ₘ-Ph-CₙH₂ₙ—NR³—CₓH₂ₓ)—, —(CₘH₂ₘ—Cy-CₙH₂ₙ—O—CₓH₂ₓ)—, or —(CₘH₂ₘ-Cy-CₙH₂ₙ—NR³—CₓH₂ₓ)—, m=1-5, n=1-5, x=1-5, Cy is cyclohexyl group, and R³ is linear or branched C₁₋₅ alkyl group or hydrogen; and D is

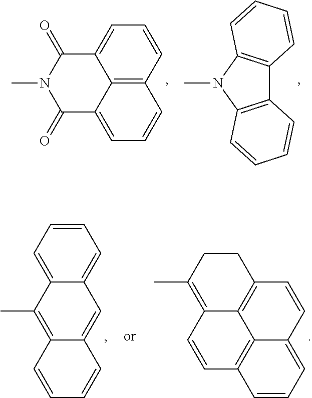

In some embodiments, the resin includes hydrogenated styrene elastomer resin, acrylate elastomer resin, or ethylene vinyl acetate copolymer.

In some embodiments, the hydrogenated styrene elastomer resin includes hydrogenated poly(styrene-b-isoprene), hydrogenated poly(styrene-b-isoprene-b-styrene), hydrogenated poly(styrene-b-butadiene-b-styrene), hydrogenated poly(styrene-b-isoprene/butadiene-b-styrene, hydrogenated poly(styrene-b-vinyl bonded rich polyisoprene), or a combination thereof.

In some embodiments, the acrylate elastomer resin includes poly(methyl methacrylate-b-isoprene), poly(methyl methacrylate-butadiene), poly(methyl methacrylate-b-isoprene-b-methyl methacrylate), poly(methyl methacrylate-b-butadiene-b-methyl methacrylate), poly(methyl methacrylate-b-isoprene/butadiene-b-methyl methacrylate), poly(methyl methacrylate-b-vinyl bonded rich polyisoprene), or a combination thereof.

One embodiment of the disclosure provides a module structure, including a front sheet; a back sheet opposite to the front sheet; and a solar cell disposed between the front sheet and the back sheet, wherein a first encapsulation film is disposed between the solar cell and the front sheet; and a second encapsulation film disposed between the solar cell and the back sheet, wherein the first encapsulation film and the second encapsulation film include an encapsulation material, including: a resin; and a fluorescent molecule, wherein the fluorescent molecule includes a fluorescent group bonded to a polyhedral oligomeric silsesquioxane.

In some embodiments, the fluorescent molecule has a chemical structure of:

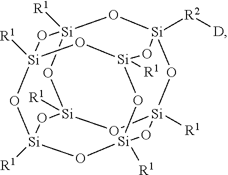

wherein R¹ is linear or branched C₃₋₁₀ alkyl group, wherein R² is —(CₘH₂ₘ)—, —(CₘH₂ₘ—O—CₓH₂ₓ)—, —(CₘH₂ₘ—NR³—CₓH₂ₓ)—, —(CₘH₂ₘ-Ph-CₙH₂ₙ—O—CₓH₂ₓ)—, —(CₘH₂ₘ-Ph-CₙH₂ₙ—NR³—CₓH₂ₓ)—, —(CₘH₂ₘ—Cy-CₙH₂ₙ—O—CₓH₂ₓ)—, or —(CₘH₂ₘ-Cy-CₙH₂ₙ—NR³—CₓH₂ₓ)—, m=1-5, n=1-5, x=1-5, Cy is cyclohexyl group, and R³ is linear or branched C₁₋₅ alkyl group or hydrogen; and D is

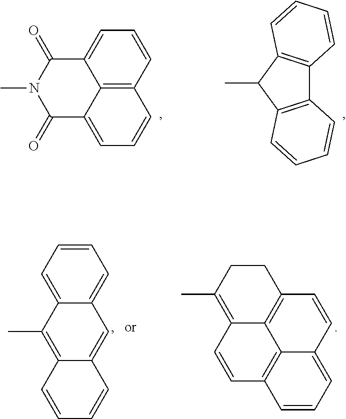

In some embodiments, the resin includes hydrogenated styrene elastomer resin, acrylate elastomer resin, or ethylene vinyl acetate copolymer.

In some embodiments, each of the front sheet and the back sheet independently includes polyolefin or glass.

In some embodiments, the solar cell includes bifacial solar cell.

In some embodiments, each of the first encapsulation film and the second encapsulation film independently has a thickness of 200 micrometers to 1000 micrometers.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows a solar cell module in one embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

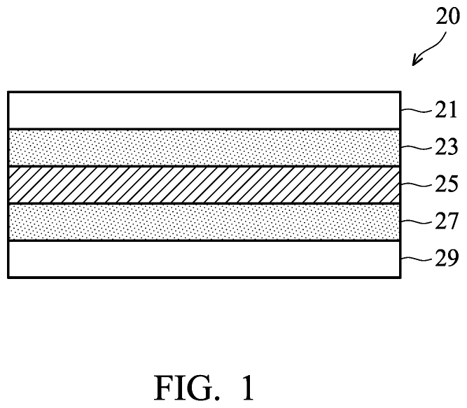

One embodiment provides an encapsulation material, which can be utilized in a module structure 20 of solar cell, as shown in FIG. 1. The module structure 20 includes a front sheet 21, a back sheet 29, and a solar cell 25 disposed between the front sheet 21 and the back sheet 29. An encapsulation film 23 is disposed between the solar cell 25 and the front sheet 21, and an encapsulation film 27 is disposed between the solar cell 25 and the back sheet 29. The encapsulation films 23 and 27 are an encapsulation material as described in detail as below. For example, the light only incidents from the front sheet 21 when the solar cell 25 is a mono-facial solar cell. The light incidents from the front sheet 21 and the back sheet 29 when the solar cell 25 is a bifacial solar cell.

The front sheet 21 and/or the back sheet 29 should have high transmittance. In one embodiment, the front sheet 21 and/or the back sheet 29 is glass or polyolefin (e.g. polymer of linear olefin or cyclic olefin). In one embodiment, the polymer of linear olefin can be polyethylene, polypropylene, ethylene/propylene copolymer, or methyl methacrylate and styrene copolymer. In one embodiment, the polymer of cyclic olefin can be ethylene propylene diene monomer (EPDM) rubber. The polyolefin can be adopted in the front sheet 21 and/or the back sheet 29 to reduce the weight of the module structure 20.

The encapsulation films 23 and 27 are encapsulation material, which includes a fluorescent group bonded to a polyhedral oligomeric silsesquioxane. In one embodiment, the fluorescent molecule of the module structure has a chemical structure of:

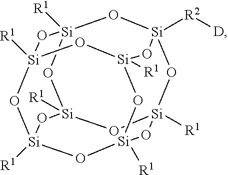

wherein R¹ is linear or branched C₃₋₁₀ alkyl group, wherein R² is —(CₘH₂ₘ)—, —(CₘH₂ₘ—O—CₓH₂ₓ)—, —(CₘH₂ₘ—NR³—CₓH₂ₓ)—, —(CₘH₂ₘ-Ph-CₙH₂ₙ—O—CₓH₂ₓ)—, —(CₘH₂ₘ-Ph-CₙH₂ₙ—NR³—CₓH₂ₓ)—, —(CₘH₂ₘ—Cy-CₙH₂ₙ—O—CₓH₂ₓ)—, or —(CₘH₂ₘ-Cy-CₙH₂ₙ—NR³—CₓH₂ₓ)—, m=1-5, n=1-5, x=1-5, Cy is cyclohexyl group, and R³ is linear or branched C₁₋₅ alkyl group or hydrogen. R² depends on the species of the polyhedral oligomeric silsesquioxane and the reactant having the fluorescent group D. In general, the fluorescent group can be bonded to the polyhedral oligomeric silsesquioxane by substitution reaction, imidization reaction, or other applicable reactions. For example, the amino group of the polyhedral oligomeric silsesquioxane can be reacted with the anhydride group of the small fluorescent molecule through the imidization reaction to from imide. Alternatively, the halogen group of the polyhedral oligomeric silsesquioxane can be reacted with the hydroxyl group or amino group through the substitution reaction to from ether or amine. In some embodiments, the fluorescent group D is

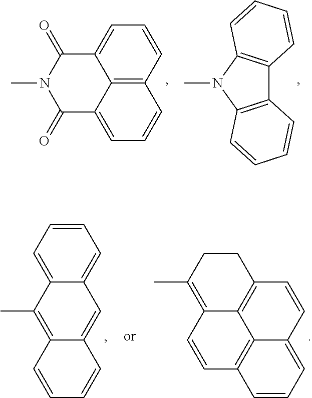

In some embodiments, the resin and the fluorescent molecule in the encapsulation material have a weight ratio of 100:0.1 to 100:5. An overly low amount of the fluorescent molecule neither efficiently converses the UV to visible light, nor increases the photoelectric conversion efficiency of the solar cell. An overly high amount of the fluorescent molecule may increase the haze and lower the transmittance of the encapsulation film, thereby lowering the photoelectric conversion efficiency of the solar cell. In one embodiment, the resin of the module structure includes hydrogenated styrene elastomer resin, acrylate elastomer resin, or ethylene vinyl acetate copolymer (EVA). While encapsulating the solar cell, the flowability of the encapsulant is positively correlated with the cell encapsulation yield. An overly low encapsulation flowability cannot form a uniform film to wrap the solar cell, even break the solar cell. An overly high encapsulation flowability may cause a problem of serious excessive glue, such that the thickness of the encapsulation film is reduced, and the solar cell cannot be sufficiently protected by the encapsulation film. Therefore, it is critical to adjust the flowability of the encapsulation material. The original hydrogenated styrene elastomer resin has a viscosity greater than 4000 pas at 150° C. The viscosity of the hydrogenated styrene elastomer resin can be reduced by adding the fluorescent molecule (less than 4000 pas at 150° C.), such that the encapsulation film has a higher flowability.

In one embodiment, the hydrogenated styrene elastomer resin includes hydrogenated poly(styrene-b-isoprene), hydrogenated poly(styrene-b-isoprene-b-styrene), hydrogenated poly(styrene-b-butadiene-b-styrene), hydrogenated poly(styrene-b-isoprene/butadiene-b-styrene, hydrogenated poly(styrene-b-vinyl bonded rich polyisoprene), or a combination thereof. The styrene block may occupy about 10 wt % to 35 wt % of the hydrogenated styrene elastomer resin. In one embodiment, the styrene block occupies about 12 wt % to 20 wt % of the hydrogenated styrene elastomer resin. An overly low amount of the styrene block in the copolymer may lower the hardness and degrade the mechanical tensile strength of the copolymer. An overly high amount of the styrene block in the copolymer may enhance the hardness and the mechanical strength of the copolymer, however, the flowability of the copolymer is degraded and unfavorable to process, and the glass transfer temperature (Tg) is also increased to lower the adhesive properties of the copolymer.

The molecular weight of the hydrogenated styrene elastomer resin is negatively correlated with the melting index of the hydrogenated styrene elastomer resin. A higher melting index of the hydrogenated styrene elastomer resin means a lower molecular weight of the hydrogenated styrene elastomer resin, and a lower melting index of the hydrogenated styrene elastomer resin means a higher molecular weight of the hydrogenated styrene elastomer resin. In one embodiment, the hydrogenated styrene elastomer resin has a melting index of about 1.0 g/10 min to 8.0 g/10 min (190° C./2.16 kg load), or about 3.5 g/10 min to 6.5 g/10 min (190° C./2.16 kg load). A hydrogenated styrene elastomer resin with an overly low melting index cannot flow smoothly to form a uniform film to wrap the solar cell during encapsulation at 150° C. due to its poor flowability. Moreover, the partially stagnant part may result in height difference, which may break the solar cell. A hydrogenated styrene elastomer resin with an overly high melting index has a problem of serious excessive glue due to its overly high flowability. As such, the thickness of the encapsulation film is reduced, and the solar cell cannot be sufficiently protected by the encapsulation film.

In some embodiments, the acrylate elastomer resin includes poly(methyl methacrylate-b-isoprene), poly(methyl methacrylate-butadiene), poly(methyl methacrylate-b-isoprene-b-methyl methacrylate), poly(methyl methacrylate-b-butadiene-b-methyl methacrylate), poly(methyl methacrylate-b-isoprene/butadiene-b-methyl methacrylate), poly(methyl methacrylate-b-vinyl bonded rich polyisoprene), or a combination thereof. The methyl methacrylate block may occupy about 10 wt % to 35 wt % of the acrylate elastomer resin. In one embodiment, the methyl methacrylate block occupies about 12 wt % to 25 wt % of the acrylate elastomer resin. An overly low amount of the methyl methacrylate block in the copolymer may lower the hardness and degrade the mechanical tensile strength of the copolymer. An overly high amount of the methyl methacrylate block in the copolymer may enhance the hardness and the mechanical strength of the copolymer, however, the flowability of the copolymer is degraded and unfavorable to process, and the glass transfer temperature (Tg) is also increased to lower the adhesive properties of the copolymer.

The molecular weight of the acrylate elastomer resin is negatively correlated with the melting index of the acrylate elastomer resin. A higher melting index of the acrylate elastomer resin means a lower molecular weight of the acrylate elastomer resin, and a lower melting index of the acrylate elastomer resin means a higher molecular weight of the acrylate elastomer resin. In one embodiment, the acrylate elastomer resin has a melting index of about 10 g/10 min to 40 g/10 min (190° C./2.16 kg load), or about 25 g/10 min to 35 g/10 min (190° C./2.16 kg load). A acrylate elastomer resin with an overly low melting index cannot flow smoothly to form a uniform film to wrap the solar cell during encapsulation at 150° C. due to its poor flowability. Moreover, the partially stagnant part may result in height difference, which may break the solar cell. An acrylate elastomer resin with an overly high melting index has a problem of serious excessive glue due to its overly high flowability. As such, the thickness of the encapsulation film is reduced, and the solar cell cannot be sufficiently protected by the encapsulation film.

The molecular weight of EVA is negatively correlated with the melting index of EVA. A higher melting index of EVA means a lower molecular weight of EVA, and a lower melting index of EVA means a higher molecular weight of EVA. In one embodiment, the EVA has a melting index of about 10 g/10 min to 80 g/10 min (190° C./2.16 kg load), or about 20 g/10 min to 55 g/10 min (190° C./2.16 kg load). An EVA with an overly low melting index cannot flow smoothly to form a uniform film to wrap the solar cell during encapsulation at 150° C. due to its poor flowability. Moreover, the partially stagnant part may result in height difference, which may break the solar cell. An EVA with an overly high melting index has a problem of serious excessive glue due to its overly high flowability. As such, the thickness of the encapsulation film is reduced, and the solar cell cannot be sufficiently protected by the encapsulation film.

In one embodiment, each of the encapsulation films 23 and 27 independently has a thickness of 200 micrometers to 1000 micrometers. The insulation films 23 and 27 with overly thin thicknesses cannot efficiently protect the solar cell 25. The insulation films 23 and 27 with overly thick thicknesses cannot further enhance the protection effect but increase the cost and the thickness of the module structure 20.

In one embodiment, pigment, anti-oxidation agent, or a combination can be further added to the front sheet 21, the back sheet 29, the encapsulation film 23, and/or the encapsulation film 27. The pigment such as carbon black or pigment master batch (e.g. CLARIANT REMAFIN polyolefin pigment masterbatch) may exchange the appearance color of the module structure to match the entire style of buildings. The anti-oxidation agent such as butylated hydroxytoluene (BHT), bis(2,2,6,6-tetramethyl-1-piperidinyloxy-4-yl) sebacate, benzophenone, a derivative thereof, or a combination thereof may prevent the above layers from yellowing. In general, the amount of the above additives is about 0.1 wt % to 10 wt %, or about 5 wt % to 10 wt %, of the front sheet 21, the back sheet 29, the encapsulation film 23, and/or the encapsulation film 27. Too much additive may hinder the processability of the front sheet 21, the back sheet 29, the encapsulation film 23, and/or the encapsulation film 27.

In some embodiments, the encapsulation films 23 and 27 can be same films of same composition and thickness. Alternatively, the encapsulation films 23 and 27 can be different films of different compositions and/or thicknesses. Regardless of the designs, the encapsulation films 23 and 27 in the embodiments of the disclosure may efficiently protect the solar cell 25 in the module structure 20, thereby improving the photoelectric conversion efficiency and lowering the potential induced degradation of the solar cell 25.

Below, exemplary embodiments will be described in detail with reference to the accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

### EXAMPLES

### Synthesis Example 1 (NI-POSS265)

2.03 g of 1,8-naphthalic anhydride (0.01024 mole, commercially available from Acros) was dissolved in 50 mL of 1-methyl-2-pyrrolidone (NMP, commercially available from Echo). 8.75 g of polyhedral oligomeric silsesquioxane POSS-AM0265 (0.01 mole, commercially available from Hybrid Plastic Inc.) was added to the NMP solution. The solution was then degassed, stirred, and heated to 140° C. and reacted at 140° C. for 5 hours. The reaction result was transparent clear orange solution. The reaction result was then cooled down and then dropwise added to 150 mL of de-ionized water to precipitate white solid. After standing for 2 hours, the suspension was filtered to collect a filtered cake (white solid). The filtered cake was washed with ethanol, and then put into a vacuum oven and dried at 80° C. for 4 hours, thereby obtaining 7.75 g of product (yield=72.24%). The ¹H NMR spectrum of the product is as follows: (CDCl₃, ppm) δ: 7.99-7.56 (m, 6H, Ar—H), 3.25-3.20 (t, 2H, N—CH₂—C), 1.7-1.8 (m, 7H, C—CH—C—Si), 3.20-3.25 (m, 2H, C—CH₂—C—Si). In UV-VIS spectrum of the product, maximum emission wavelength is 410 nm. The above reaction is shown below:

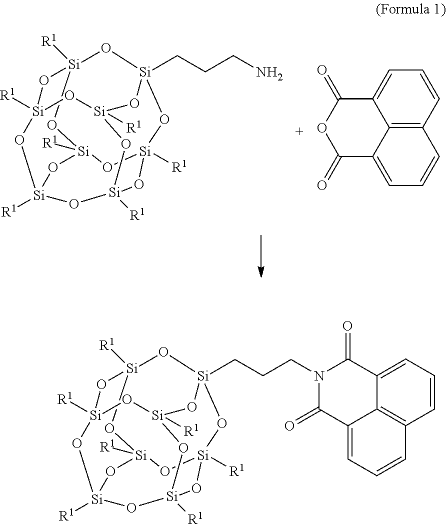

### Synthesis Example 2 (AN-POSS615)

2.133 g of 9-anthraence methanol (0.1024 mole, commercially available from Acros) was dissolved in 50 mL of toluene (commercially available from Echo). 8.75 g of polyhedral oligomeric silsesquioxane POSS-HA0615 (0.01 mole, commercially available from Hybrid Plastic Inc.), 1.714 g of potassium iodide (0.1024 mole, commercially available from Showa Chem), and 0.691 g of potassium carbonate (0.005 mole, commercially available from Showa Chem) were added to the toluene solution. The solution was then degassed, stirred, and heated to 110° C. and reacted at 110° C. under nitrogen for 8 hours. The reaction result was cooled down to room temperature, which was transparent pale yellow semi-solid. The semi-solid was filtered and washed with toluene to collect transparent colorless filtrate. Most of the solvent in the filtrate was removed by a rotary evaporator, and solid was therefore precipitated. The precipitate was collected as a filtered cake by filtering. The filtered cake was washed with ethanol, and then dried to obtain 7.22 g of product (yield=63.23%). The ¹H NMR spectrum of the product is as follows: (CDCl₃, ppm) δ: 7.30-7.75 (m, 9H, Ar—H), 7.20-7.40 (dd, 4H, Ar—H), 5.05-5.09 (s, 2H, Ar—CH₂—O), 4.55-4.65 (s, 2H, Ar—CH₂—O), 1.7-1.8 (m, 7H, C—CH—C—Si). The above reaction is shown below:

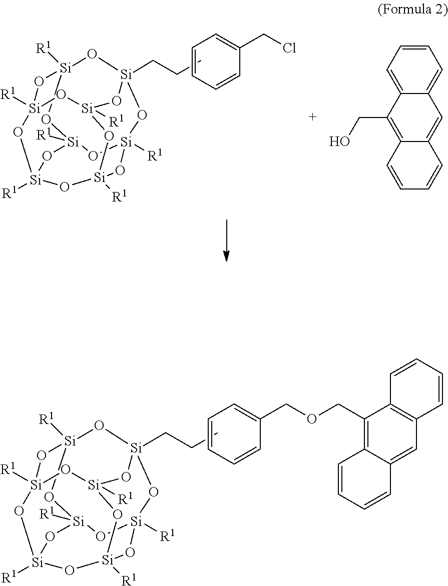

### Synthesis Example 3 (NI-POSS635)

23.78 g of 1,8-naphthalic anhydride (0.12 mole, commercially available from Acros) was added to 100 mL of an ethanol solution of 3-amino propanol (containing 18.026 g of 3-amino propanol (0.24 mol), and then heated to 70° C. and reacted at 70° C. for 5 hours. The reaction was cooled to room temperature and then filtered to collect a filtered cake. The filtered cake was added to 95% ethanol and heated to be dissolved, and then cooled down to re-crystallize a solid. The re-crystallized solid was collected by filtering, and then vacuum dried to obtain 22.3 g of white needle-shaped product (yield=72.8%). The melting point of the product was 122° C. to 123° C., which was determined by differential scanning calorimeter (DSC). The ¹H NMR spectrum of the product is as follows: (500 MHz, CDCl₃): δ: 8.53 (d, 2H), 8.16 (d, 2H), 7.69-7.68 (m, 2H), 4.27 (t, 2H), 3.52-3.51 (m, 2H), 3.16 (s, 1H), 1.94-1.90 (m, 2H). The FTIR spectrum of the product is as follows: 3460, 3192, 2953, 2860, 2401, 1693, 1653, 1622, 1587, 1444, 1392, 1361, 1350, 1242, 1274, 1170, 1074, 1058. The above reaction is shown below:

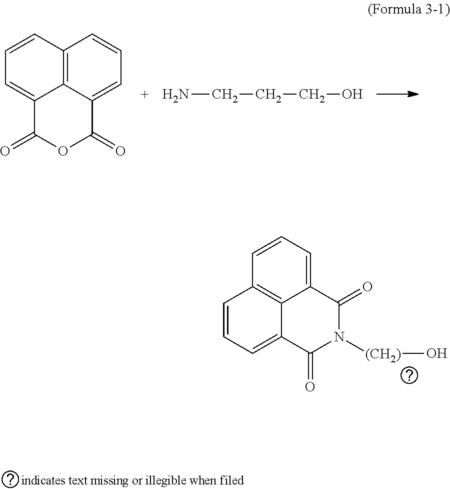

2.6139 g of the white needle-shaped solid product (0.0124 g mole) was dissolved in 50 mL of toluene (commercially available from Echo). 8.951 g of the polyhedral oligomeric silsesquioxane POSS-HA0635 (0.01 mole, commercially available from Hybrid Plastic Inc.), 1.714 g of potassium iodide (0.1024 mole, commercially available from Showa Chem), and 0.691 g of potassium carbonate (0.005 mole, commercially available from Showa Chem) were added to the toluene solution. The solution was then degassed, stirred, and heated to 110° C. and reacted at 110° C. under nitrogen for 8 hours. The reaction result was cooled down to room temperature, which was transparent pale yellow semi-solid. The semi-solid was filtered and washed with toluene to collect transparent colorless filtrate. Most of the solvent in the filtrate was removed by a rotary evaporator, and solid was therefore precipitated. The precipitate was collected as a filtered cake by filtering. The filtered cake was washed with ethanol, and then dried in a vacuum oven at 80° C. for 4 hours to obtain 8.8 g of product (yield=79.08%). The ¹H NMR spectrum of the product is as follows: (CDCl₃, ppm) δ: 7.56-7.99 (m, 6H), 3.35-3.39 (t, 4H, O—CH₂), 3.20-3.25 (t, 2H, N—CH₂—), 1.7-1.8 (m, 7H, C—CH—C). In UV-VIS spectrum of the product, maximum emission wavelength is 374 nm. The above reaction is shown below:

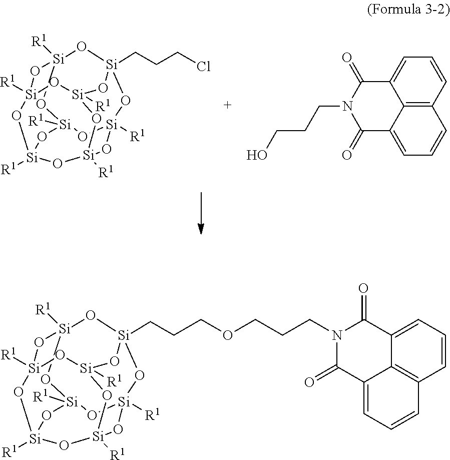

### Synthesis Example 4 (AN-POSS635)

2.1333 g of 9-anthracenemethanol (0.0124 mole) was dissolved in 50 mL of toluene (commercially available from Echo). 8.951 g of the polyhedral oligomeric silsesquioxane POSS-HA0635 (0.01 mole, commercially available from Hybrid Plastic Inc.), 1.714 g of potassium iodide (0.1024 mole, commercially available from Showa Chem), and 0.691 g of potassium carbonate (0.005 mole, commercially available from Showa Chem) were added to the toluene solution. The solution was then degassed, stirred, and heated to 110° C. and reacted at 110° C. under nitrogen for 8 hours. The reaction result was cooled down to room temperature, which was transparent pale yellow semi-solid. The semi-solid was filtered and washed with toluene to collect transparent colorless filtrate. Most of the solvent in the filtrate was removed by a rotary evaporator, and solid was therefore precipitated. The precipitate was collected as a filtered cake by filtering. The filtered cake was washed with ethanol, and then dried in a vacuum oven at 80° C. for 4 hours to obtain 8.72 g of product (yield=81.8%). The ¹H NMR spectrum of the product is as follows: (CDCl₃, ppm) δ: 7.30-7.75 (m, 9H, Ar—H), 5.05-5.09 (s, 2H, Ar—CH₂—O), 3.35-3.39 (t, 4H, O—CH₂), 1.7-1.8 (m, 7H, C—CH—C—Si). In UV-VIS spectrum of the product, maximum emission wavelength is 390 nm. The above reaction is shown below:

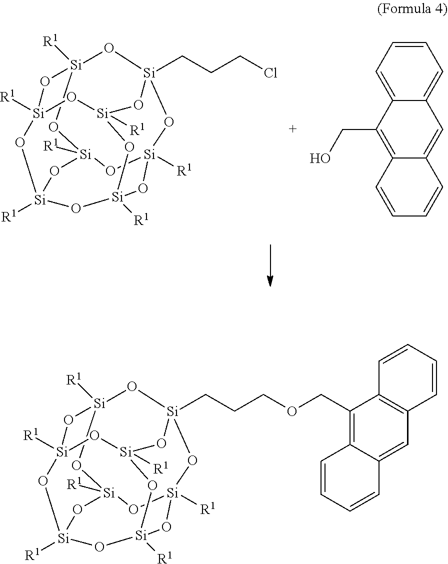

### Synthesis Example 5 (CZ-POSS635)

2.1633 g of N-hydroxyethyl carbazole (0.0124 mole) was dissolved in 50 mL of toluene (commercially available from Echo). 8.951 g of the polyhedral oligomeric silsesquioxane POSS-HA0635 (0.01 mole, commercially available from Hybrid Plastic Inc.), 1.714 g of potassium iodide (0.1024 mole, commercially available from Showa Chem), and 0.691 g of potassium carbonate (0.005 mole, commercially available from Showa Chem) were added to the toluene solution. The solution was then degassed, stirred, and heated to 110° C. and reacted at 110° C. under nitrogen for 8 hours. The reaction result was cooled down to room temperature, which was transparent pale yellow semi-solid. The semi-solid was filtered and washed with toluene to collect transparent colorless filtrate. Most of the solvent in the filtrate was removed by a rotary evaporator, and solid was therefore precipitated. The precipitate was collected as a filtered cake by filtering. The filtered cake was washed with ethanol, and then dried in a vacuum oven at 80° C. for 4 hours to obtain 8.4 g of product (yield=78.6%). The ¹H NMR spectrum of the product is as follows: (CDCl₃, ppm) δ: 7.36-7.12 (m, 8H, Ar—H), 4.15-4.02 (t, 2H, N—CH₂—C), 3.85-3.80 (t, 2H, O—CH₂—), 3.40-3.30 (t, 2H, O—CH₂—C—Si), 1.7-1.8 (m, 7H, C—CH—C—Si), 1.6-1.45 (t, 2H, C—CH₂—C—Si). In UV-VIS spectrum of the product, maximum emission wavelength is 350 nm. The above reaction is shown below:

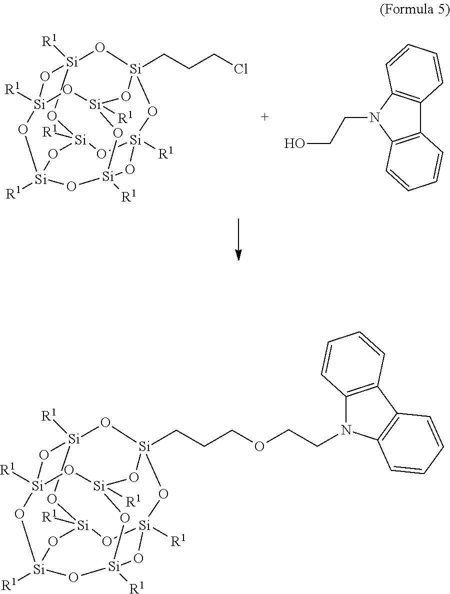

### Example 1

10 kg of hydrogenated styrene elastomer resin S1611 (commercially available from Asahi chemical Co. Ltd.) and 0.01 kg of the fluorescent product from Synthesis Example 1 were put into a single screw blender FRP-V32C (commercially available from MEISEI KINZOKU MFG. CO. LTD.) to be pelletized to serve as a composition of a light conversion layer. The temperature of the single screw blender was set at 120° C. to 150° C., and the optimal temperature was set as four segments, such as 130° C., 140° C., 140° C., and 130° C. After pelletization, the pellets of the light conversion layer were extruded by an extruder HP-50 (commercially available from GANG LING MACHINERY CO., LTD.) to form a film. The pellets was pre-heated at 150° C. for 10 minutes, and then pressed at 150° C. by a pressure of 100 kg/cm² for 10 minutes to form an encapsulation film with a thickness of 545 micrometers. The transmittance, the viscosity at 150° C., the haze, the breakdown voltage, the volume resistivity, and the encapsulation ability (whether obvious breakage occurred) of the encapsulation film are listed in Table 1.

A commercially available solar cell (Motech Industries Inc.) was selected to measure its short-circuit current (Isc) and maximum output power gain (Pₘₐₓ). The encapsulation film was put on a front sheet (super clear glass, commercially available from TAIWAN GLASS IND. CORP.), and the other encapsulation film was put on a back sheet (commercially available from Taiflex scientific CO. LTD.). The solar cell was interposed between the encapsulation film on the back sheet and the encapsulation film on the front sheet, and then heated and laminated in a vacuum lamination device to complete an encapsulated module structure. Afterward, the short-circuit current and the maximum output power of the encapsulated solar cell were measured to calculate the short-circuit current gain and the maximum output power gain of the module structure, as shown in Table 2.

Four (2×2) series-connected solar cells (Motech Industries Inc.) were interposed between the encapsulation film on the back sheet and the encapsulation film on the front sheet, and then heated and laminated in a vacuum lamination device to complete an encapsulated module structure. The potential induced degradation (PID) of the encapsulated solar cell was measured, as shown in Table 3.

### Example 2

10 kg of hydrogenated styrene elastomer resin S1611 (commercially available from Asahi chemical Co. Ltd.) and 0.05 kg of the fluorescent product from Synthesis Example 1 were put into a single screw blender FRP-V32C (commercially available from MEISEI KINZOKU MFG. CO. LTD.) to be pelletized to serve as a composition of a light conversion layer. The temperature of the single screw blender was set at 120° C. to 150° C., and the optimal temperature was set as four segments, such as 130° C., 140° C., 140° C., and 130° C. After pelletization, the pellets of the light conversion layer were extruded by an extruder HP-50 (commercially available from GANG LING MACHINERY CO., LTD.) to form a film. The pellets was pre-heated at 150° C. for 10 minutes, and then pressed at 150° C. by a pressure of 100 kg/cm² for 10 minutes to form an encapsulation film with a thickness of 637 micrometers. The transmittance, the viscosity at 150° C., the haze, the breakdown voltage, the volume resistivity, and the encapsulation ability (whether obvious breakage occurred) of the encapsulation film are listed in Table 1.

The encapsulation film was put on a front sheet (super clear glass, commercially available from TAIWAN GLASS IND. CORP.), and the other encapsulation film was put on a back sheet (commercially available from Taiflex scientific CO. LTD.). The commercially available solar cell (Motech Industries Inc.) was interposed between the encapsulation film on the back sheet and the encapsulation film on the front sheet, and then heated and laminated in a vacuum lamination device to complete an encapsulated module structure. Afterward, the short-circuit current and the maximum output power of the encapsulated solar cell were measured to calculate the short-circuit current gain and the maximum output power gain of the module structure, as shown in Table 2.

### Example 3

10 kg of hydrogenated styrene elastomer resin S1611 and 0.1 kg of the fluorescent product from Synthesis Example 1 were put into a single screw blender FRP-V32C (commercially available from MEISEI KINZOKU MFG. CO. LTD.) to be pelletized to serve as a composition of a light conversion layer. The temperature of the single screw blender was set at 120° C. to 150° C., and the optimal temperature was set as four segments, such as 130° C., 140° C., 140° C., and 130° C. After pelletization, the pellets of the light conversion layer were extruded by an extruder HP-50 (commercially available from GANG LING MACHINERY CO., LTD.) to form a film. The pellets was pre-heated at 150° C. for 10 minutes, and then pressed at 150° C. by a pressure of 100 kg/cm² for 10 minutes to form an encapsulation film with a thickness of 497 micrometers. The transmittance, the viscosity at 150° C., the haze, the breakdown voltage, the volume resistivity, and the encapsulation ability (whether obvious breakage occurred) of the encapsulation film are listed in Table 1.

The encapsulation film was put on a front sheet (super clear glass, commercially available from TAIWAN GLASS IND. CORP.), and the other encapsulation film was put on a back sheet (commercially available from Taiflex scientific CO. LTD.). The commercially available solar cell (Motech Industries Inc.) was interposed between the encapsulation film on the back sheet and the encapsulation film on the front sheet, and then heated and laminated in a vacuum lamination device to complete an encapsulated module structure. Afterward, the short-circuit current and the maximum output power of the encapsulated solar cell were measured to calculate the short-circuit current gain and the maximum output power gain of the module structure, as shown in Table 2.

TABLE 1

| | Example 1 | Example 2 | Example 3 |
|---|---|---|---|
| Resin | Hydrogenated styrene | Hydrogenated styrene | Hydrogenated styrene |
| | elastomer resin | elastomer resin | elastomer resin |
| Fluorescent | Synthesis Example 1, | Synthesis Example 1, | Synthesis Example 1, |
| molecule (%) | NI-POSS265 (0.1%) | NI-POSS265 (0.5%) | NI-POSS265 (1%) |
| Transmittance | 97.42% | 97% | 97.6% |
| Viscosity @150° C. | 3210 | 3190 | 3174 |
| (Pa · S) | | | |
| Haze | 7.53 | 5.3 | 3.22 |
| Thickness | 545 μm | 637 μm | 497 μm |
| Breakdown voltage | 20 | 20.5 | 20.4 |
| (KV) | | | |
| Breakdown voltage | 36.7 | 32.2 | 41.0 |
| (KV)/Thickness | | | |
| (mm) | | | |
| Volume resistivity | 9.68E15 | 8.76E15 | 9.22E15 |
| (Ω · cm) | | | |
| Encapsulation | Excellent | Excellent | Excellent |
| ability | | | |

In Table 1, the thickness was measured by a film thickness meter, the transmittance was measured by the standard ASTM D1003, the viscosity was measured by a rheometer AR2000 (TA instruments), the haze was measured by the standard ASTM D1003, the breakdown voltage was measured by the standard ASTM D149, and the volume resistivity was measured by the standard ASTM D257.

TABLE 2

| | Example 1 | Example 2 | Example 3 |
|---|---|---|---|
| Resin | Hydrogenated styrene | Hydrogenated styrene | Hydrogenated styrene |
| | elastomer resin | elastomer resin | elastomer resin |
| Fluorescent | Synthesis Example 1, | Synthesis Example 1, | Synthesis Example 1, |
| molecule (%) | NI-POSS265 (0.1%) | NI-POSS265 (0.5%) | NI-POSS265 (1%) |
| Short-circuit | 5.43% | 4.92% | 5.2% |
| current gain (%) | | | |
| Maximum | 4.67% | 3.59% | 4.55% |
| output power | | | |
| gain (%) | | | |

In Table 2, the maximum output power gain was measured by the standard IEC60891, and the short-circuit current gain was measured by the standard IEC60891. As shown in Table 2, the fluorescent molecule grafting the POSS may convert the UV in sunlight into visible light, so that the encapsulation film containing the fluorescent molecule grafting the POSS may increase the photoelectric conversion efficiency of the solar cell in the module structure.

TABLE 3

| | | | | Comparative | Comparative | Comparative | Comparative | Comparative |
|---|---|---|---|---|---|---|---|---|
| | Example 1 | Example 4 | Example 5 | Example 1 | Example 2 | Example 3 | Example 4 | Example 5 |
| Resin | Hydrogenated | EVA | EVA | EVA | Hydrogenated | Hydrogenated | Hydrogenated | Hydrogenated |
| | styrene | | | | styrene | styrene | styrene | styrene |
| | elastomer | | | | elastomer | elastomer | elastomer | elastomer |
| | resin | | | | resin | resin | resin | resin |
| Additive | Synthesis | Synthesis | Synthesis | None | None | POSS265 | Blend | Blend |
| (%) | Example | Example | Example | | | (1%) | with | with |
| | 1 (NI- | 4 (AN- | 4 (AN- | | | | POSS265 | POSS265 |
| | POSS265 | POSS635 | POSS635 | | | | (0.25%) | (1%) and |
| | 0.1%) | 0.1%) | 0.25%) | | | | and N- | N- |
| | | | | | | | hydroxy | hydroxy |
| | | | | | | | propyl- | propyl- |
| | | | | | | | 1,8- | 1,8- |
| | | | | | | | naphthalene | naphthalene |
| | | | | | | | diimide | diimide |
| | | | | | | | (0.25%) | (1%) |
| PID-168 hrs | Not | 6.29% | 2.65% | 8.85% | Not | Not | 21.24% | 12.85% |
| | measured | | | | measured | measured | | |
| PID-288 hrs | 1.62% | 15.27% | 4.08% | >30% | 2.81% | 1.92% | 30.72% | 18.02% |

In Table 3, the potential induced degradation (PID) was measured by the standard IEC62804. As shown in Table 3, compared to the encapsulation film containing the mixture of small fluorescent molecule and polyhedral oligomeric silsesquioxane in Comparative Examples (or a general encapsulation film such as EVA or hydrogenated styrene elastomer resin), the encapsulation film containing the fluorescent molecule (fluorescent group bonded to the polyhedral oligomeric silsesquioxane) in Examples could further lower the PID in the module structure of the solar cell.

### Example 4

10 kg of EVA (SUMITOMOKA40, VA content: 28%) and 0.01 kg of the fluorescent product (AN-POSS635) from Synthesis Example 4 were put into a single screw blender FRP-V32C (commercially available from MEISEI KINZOKU MFG. CO. LTD.) to be pelletized to serve as a composition of a light conversion layer. The temperature of the single screw blender was set at 70° C. to 90° C., and the optimal temperature was set as four segments, such as 70° C., 80° C., 80° C., and 70° C. After pelletization, the pellets of the light conversion layer were extruded by an extruder HP-50 (commercially available from GANG LING MACHINERY CO., LTD.) to form a film. The pellets was pre-heated at 90° C. for 10 minutes, and then pressed at 90° C. by a pressure of 100 kg/cm² for 10 minutes to form an encapsulation film with a thickness of 563 micrometers. The transmittance, the haze, the breakdown voltage, the volume resistivity, and the encapsulation ability (whether obvious breakage occurred) of the encapsulation film are listed in Table 4.

The encapsulation film was put on a front sheet (super clear glass, commercially available from TAIWAN GLASS IND. CORP.), and the other encapsulation film was put on a back sheet (commercially available from Taiflex scientific CO. LTD.). The commercially available solar cell (Motech Industries Inc.) was interposed between the encapsulation film on the back sheet and the encapsulation film on the front sheet, and then heated and laminated in a vacuum lamination device to complete an encapsulated module structure. Afterward, the short-circuit current and the maximum output power of the encapsulated solar cell were measured to calculate the short-circuit current gain and the maximum output power gain of the module structure, as shown in Table 5.

Four (2×2) series-connected solar cells (Motech Industries Inc.) were interposed between the encapsulation film on the back sheet and the encapsulation film on the front sheet, and then heated and laminated in a vacuum lamination device to complete an encapsulated module structure. The potential induced degradation (PID) of the encapsulated solar cell was measured, as shown in Table 3.

### Example 5

10 kg of EVA (SUMITOMOKA40, VA content: 28%) and 0.025 kg of the fluorescent product (AN-POSS635) from Synthesis Example 4 were put into a single screw blender FRP-V32C (commercially available from MEISEI KINZOKU MFG. CO. LTD.) to be pelletized to serve as a composition of a light conversion layer. The temperature of the single screw blender was set at 70° C. to 90° C., and the optimal temperature was set as four segments, such as 70° C., 80° C., 80° C., and 70° C. After pelletization, the pellets of the light conversion layer were extruded by an extruder HP-50 (commercially available from GANG LING MACHINERY CO., LTD.) to form a film. The pellets was pre-heated at 90° C. for 10 minutes, and then pressed at 90° C. by a pressure of 100 kg/cm² for 10 minutes to form an encapsulation film with a thickness of 524 micrometers. The transmittance, the haze, the breakdown voltage, the volume resistivity, and the encapsulation ability (whether obvious breakage occurred) of the encapsulation film are listed in Table 4.

The encapsulation film was put on a front sheet (super clear glass, commercially available from TAIWAN GLASS IND. CORP.), and the other encapsulation film was put on a back sheet (commercially available from Taiflex scientific CO. LTD.). The commercially available solar cell (Motech Industries Inc.) was interposed between the encapsulation film on the back sheet and the encapsulation film on the front sheet, and then heated and laminated in a vacuum lamination device to complete an encapsulated module structure. Afterward, the short-circuit current and the maximum output power of the encapsulated solar cell were measured to calculate the short-circuit current gain and the maximum output power gain of the module structure, as shown in Table 5.

Four (2×2) series-connected solar cells (Motech Industries Inc.) were interposed between the encapsulation film on the back sheet and the encapsulation film on the front sheet, and then heated and laminated in a vacuum lamination device to complete an encapsulated module structure. The potential induced degradation (PID) of the encapsulated solar cell was measured, as shown in Table 3.

TABLE 4

| | Example 4 | Example 5 |
|---|---|---|
| Resin | EVA | EVA |
| Fluorescent molecule | Synthesis Example 4, | Synthesis Example 4, |
| (%) | AN-POSS635 (0.1%) | AN-POSS635 (0.25%) |
| Transmittance | 98.6% | 98.2% |
| Haze | 1.42 | 7.03 |
| Thickness | 563 μm | 524 μm |
| Breakdown voltage (KV) | 19 | 16 |
| Breakdown voltage | 33.7 | 30.5 |
| (KV)/Thickness (mm) | | |
| Volume resistivity | 1.65E14 | 1.99E14 |
| (Ω · cm) | | |
| Encapsulation ability | Excellent | Excellent |

In Table 4, the thickness, the transmittance, the haze, the breakdown voltage, and the volume resistivity were measured by tools and standards similar to those in Table 1.

TABLE 5

| | Example 4 | Example5 |
|---|---|---|
| Resin | EVA | EVA |
| Fluorescent | Synthesis Example 4, | Synthesis Example 4, |
| molecule (%) | AN-POSS635 (0.1%) | AN-POSS635 (0.25%) |
| Short-circuit | 4.197% | 4.216% |
| current gain (%) | | |
| Maximum output | 3.779% | 3.222% |
| power gain (%) | | |

In Table 5, the maximum output power gain and the short-circuit current gain were measured by a standard similar to that in Example 2. As shown in Table 5, the fluorescent molecule grafting the POSS may convert the UV in sunlight into visible light, so that the encapsulation film containing the fluorescent molecule grafting the POSS may increase the photoelectric conversion efficiency of the solar cell in the module structure.

### Example 6

10 kg of acrylate elastomer resin (LA2140e, commercially available from KURARAY) and 0.01 kg of the fluorescent product (AN-POSS635) from Synthesis Example 4 were put into a single screw blender FRP-V32C (commercially available from MEISEI KINZOKU MFG. CO. LTD.) to be pelletized to serve as a composition of a light conversion layer. The temperature of the single screw blender was set at 120° C. to 150° C., and the optimal temperature was set as four segments, such as 130° C., 140° C., 140° C., and 130° C. After pelletization, the pellets of the light conversion layer were extruded by an extruder HP-50 (commercially available from GANG LING MACHINERY CO., LTD.) to form a film. The pellets was pre-heated at 150° C. for 10 minutes, and then pressed at 150° C. by a pressure of 100 kg/cm² for 10 minutes to form an encapsulation film with a thickness of 849 micrometers. The transmittance, the rheological viscosity at 150° C., the haze, the breakdown voltage, the volume resistivity, and the encapsulation ability (whether obvious breakage occurred) of the encapsulation film are listed in Table 6.

The encapsulation film was put on a front sheet (super clear glass, commercially available from TAIWAN GLASS IND. CORP.), and the other encapsulation film was put on a back sheet (commercially available from Taiflex scientific CO. LTD.). The commercially available solar cell (Motech Industries Inc.) was interposed between the encapsulation film on the back sheet and the encapsulation film on the front sheet, and then heated and laminated in a vacuum lamination device to complete an encapsulated module structure. Afterward, the short-circuit current and the maximum output power of the encapsulated solar cell were measured to calculate the short-circuit current gain and the maximum output power gain of the module structure, as shown in Table 7.

### Example 7

10 kg of acrylate elastomer resin (LA2140e, commercially available from KURARAY) and 0.025 kg of the fluorescent product (AN-POSS635) from Synthesis Example 4 were put into a single screw blender FRP-V32C (commercially available from MEISEI KINZOKU MFG. CO. LTD.) to be pelletized to serve as a composition of a light conversion layer. The temperature of the single screw blender was set at 120° C. to 150° C., and the optimal temperature was set as four segments, such as 130° C., 140° C., 140° C., and 130° C. After pelletization, the pellets of the light conversion layer were extruded by an extruder HP-50 (commercially available from GANG LING MACHINERY CO., LTD.) to form a film. The pellets was pre-heated at 150° C. for 10 minutes, and then pressed at 150° C. by a pressure of 100 kg/cm² for 10 minutes to form an encapsulation film with a thickness of 404 micrometers. The transmittance, the rheological viscosity at 150° C., the haze, the breakdown voltage, the volume resistivity, and the encapsulation ability (whether obvious breakage occurred) of the encapsulation film are listed in Table 6.

The encapsulation film was put on a front sheet (super clear glass, commercially available from TAIWAN GLASS IND. CORP.), and the other encapsulation film was put on a back sheet (commercially available from Taiflex scientific CO. LTD.). The commercially available solar cell (Motech Industries Inc.) was interposed between the encapsulation film on the back sheet and the encapsulation film on the front sheet, and then heated and laminated in a vacuum lamination device to complete an encapsulated module structure. Afterward, the short-circuit current and the maximum output power of the encapsulated solar cell were measured to calculate the short-circuit current gain and the maximum output power gain of the module structure, as shown in Table 7.

TABLE 6

| | Example 6 | Example 7 |
|---|---|---|
| Resin | Acrylate elastomer resin | Acrylate elastomer resin |
| Fluorescent | Synthesis Example 4 | Synthesis Example 4 |
| molecule (%) | (0.1%) | (0.25%) |
| Transmittance | 98.5% | 98.5% |
| Viscosity | 2427 | 1814 |
| @150° C. | | |
| (Pa · S) | | |
| Haze | 1.62 | 2.12 |
| Thickness | 849 μm | 404 μm |
| Breakdown voltage | 20 | 14.6 |
| (KV) | | |
| Breakdown voltage | 23.6 | 36.1 |
| (KV)/Thickness | | |
| (mm) | | |
| Volume resistivity | 5.55E12 | 6.37E12 |
| (Ω · cm) | | |
| Encapsulation | Excellent | Excellent |
| ability | | |

In Table 6, the thickness, the transmittance, the haze, the breakdown voltage, and the volume resistivity were measured by tools and standards similar to those in Table 1.

TABLE 7

| | Example 6 | Example 7 |
|---|---|---|
| Resin | Acrylate elastomer resin | Acrylate elastomer resin |
| Fluorescent | Synthesis Example 4 | Synthesis Example 4 |
| molecule (%) | (0.1%) | (0.25%) |
| Short-circuit | 4.484% | 4.189% |
| current gain (%) | | |
| Maximum output | 3.684% | 3.419% |
| power gain (%) | | |

In Table 7, the maximum output power gain and the short-circuit current gain were measured by a standard similar to that in Example 2. As shown in Table 7, the fluorescent molecule grafting the POSS may convert the UV in sunlight into visible light, so that the encapsulation film containing the fluorescent molecule grafting the POSS may increase the photoelectric conversion efficiency of the solar cell in the module structure.

### Comparative Example 1

10 kg of EVA (SUMITOMOKA40, VA content: 28%) was put into a single screw blender FRP-V32C (commercially available from MEISEI KINZOKU MFG. CO. LTD.) to be pelletized to serve as a composition of a light conversion layer. The temperature of the single screw blender was set at 70° C. to 90° C., and the optimal temperature was set as four segments, such as 70° C., 80° C., 80° C., and 70° C. After pelletization, the pellets of the light conversion layer were extruded by an extruder HP-50 (commercially available from GANG LING MACHINERY CO., LTD.) to form a film. The pellets was pre-heated at 90° C. for 10 minutes, and then pressed at 90° C. by a pressure of 100 kg/cm² for 10 minutes to form an encapsulation film with a thickness of 402 micrometers. The transmittance, the haze, the breakdown voltage, the volume resistivity, and the encapsulation ability (whether obvious breakage occurred) of the encapsulation film are listed in Table 8.

The encapsulation film was put on a front sheet (super clear glass, commercially available from TAIWAN GLASS IND. CORP.), and the other encapsulation film was put on a back sheet (commercially available from Taiflex scientific CO. LTD.). The commercially available solar cell (Motech Industries Inc.) was interposed between the encapsulation film on the back sheet and the encapsulation film on the front sheet, and then heated and laminated in a vacuum lamination device to complete an encapsulated module structure. Afterward, the short-circuit current and the maximum output power of the encapsulated solar cell were measured to calculate the short-circuit current gain and the maximum output power gain of the module structure, as shown in Table 9.

Four (2×2) series-connected solar cells (Motech Industries Inc.) were interposed between the encapsulation film on the back sheet and the encapsulation film on the front sheet, and then heated and laminated in a vacuum lamination device to complete an encapsulated module structure. The potential induced degradation (PID) of the encapsulated solar cell was measured, as shown in Table 3.

### Comparative Example 2

10 kg of hydrogenated styrene elastomer resin (S1611, commercially available from Asahi Chemical Co. Ltd.) was put into a single screw blender FRP-V32C (commercially available from MEISEI KINZOKU MFG. CO. LTD.) to be pelletized to serve as a composition of a light conversion layer. The temperature of the single screw blender was set at 120° C. to 150° C., and the optimal temperature was set as four segments, such as 130° C., 140° C., 140° C., and 130° C. After pelletization, the pellets of the light conversion layer were extruded by an extruder HP-50 (commercially available from GANG LING MACHINERY CO., LTD.) to form a film. The pellets was pre-heated at 150° C. for 10 minutes, and then pressed at 150° C. by a pressure of 100 kg/cm² for 10 minutes to form an encapsulation film with a thickness of 623 micrometers. The transmittance, the viscosity at 150° C., the haze, the breakdown voltage, the volume resistivity, and the encapsulation ability (whether obvious breakage occurred) of the encapsulation film are listed in Table 8.

The encapsulation film was put on a front sheet (super clear glass, commercially available from TAIWAN GLASS IND. CORP.), and the other encapsulation film was put on a back sheet (commercially available from Taiflex scientific CO. LTD.). The commercially available solar cell (Motech Industries Inc.) was interposed between the encapsulation film on the back sheet and the encapsulation film on the front sheet, and then heated and laminated in a vacuum lamination device to complete an encapsulated module structure. Afterward, the short-circuit current and the maximum output power of the encapsulated solar cell were measured to calculate the short-circuit current gain and the maximum output power gain of the module structure, as shown in Table 9.

Four (2×2) series-connected solar cells (Motech Industries Inc.) were interposed between the encapsulation film on the back sheet and the encapsulation film on the front sheet, and then heated and laminated in a vacuum lamination device to complete an encapsulated module structure. The potential induced degradation (PID) of the encapsulated solar cell was measured, as shown in Table 3.

### Comparative Example 3

10 kg of hydrogenated styrene elastomer resin (S1611, commercially available from Asahi Chemical Co. Ltd.) and 0.1 kg of polyhedral oligomeric silsesquioxane POSS-AM0265 (commercially available from Hybrid Plastic Inc.) were put into a single screw blender FRP-V32C (commercially available from MEISEI KINZOKU MFG. CO. LTD.) to be pelletized to serve as a composition of a light conversion layer. The temperature of the single screw blender was set at 120° C. to 150° C., and the optimal temperature was set as four segments, such as 130° C., 140° C., 140° C., and 130° C. After pelletization, the pellets of the light conversion layer were extruded by an extruder HP-50 (commercially available from GANG LING MACHINERY CO., LTD.) to form a film. The pellets was pre-heated at 150° C. for 10 minutes, and then pressed at 150° C. by a pressure of 100 kg/cm² for 10 minutes to form an encapsulation film with a thickness of 497 micrometers. The transmittance, the viscosity at 150° C., the haze, the breakdown voltage, the volume resistivity, and the encapsulation ability (whether obvious breakage occurred) of the encapsulation film are listed in Table 8.

The encapsulation film was put on a front sheet (super clear glass, commercially available from TAIWAN GLASS IND. CORP.), and the other encapsulation film was put on a back sheet (commercially available from Taiflex scientific CO. LTD.). The commercially available solar cell (Motech Industries Inc.) was interposed between the encapsulation film on the back sheet and the encapsulation film on the front sheet, and then heated and laminated in a vacuum lamination device to complete an encapsulated module structure. Afterward, the short-circuit current and the maximum output power of the encapsulated solar cell were measured to calculate the short-circuit current gain and the maximum output power gain of the module structure, as shown in Table 9.

Four (2×2) series-connected solar cells (Motech Industries Inc.) were interposed between the encapsulation film on the back sheet and the encapsulation film on the front sheet, and then heated and laminated in a vacuum lamination device to complete an encapsulated module structure. The potential induced degradation (PID) of the encapsulated solar cell was measured, as shown in Table 3.

### Comparative Example 4

10 kg of hydrogenated styrene elastomer resin (S1611, commercially available from Asahi Chemical Co. Ltd.), 0.025 kg of polyhedral oligomeric silsesquioxane POSS-AM0265 (commercially available from Hybrid Plastic Inc.), and 0.025 kg of N-hydroxypropyl-1,8-naphthalene diimide were put into a single screw blender FRP-V32C (commercially available from MEISEI KINZOKU MFG. CO. LTD.) to be pelletized to serve as a composition of a light conversion layer. The temperature of the single screw blender was set at 120° C. to 150° C., and the optimal temperature was set as four segments, such as 130° C., 140° C., 140° C., and 130° C. After pelletization, the pellets of the light conversion layer were extruded by an extruder HP-50 (commercially available from GANG LING MACHINERY CO., LTD.) to form a film. The pellets was pre-heated at 150° C. for 10 minutes, and then pressed at 150° C. by a pressure of 100 kg/cm² for 10 minutes to form an encapsulation film with a thickness of 683 micrometers. The transmittance, the viscosity at 150° C., the haze, the breakdown voltage, the volume resistivity, and the encapsulation ability (whether obvious breakage occurred) of the encapsulation film are listed in Table 8.

The encapsulation film was put on a front sheet (super clear glass, commercially available from TAIWAN GLASS IND. CORP.), and the other encapsulation film was put on a back sheet (commercially available from Taiflex scientific CO. LTD.). The commercially available solar cell (Motech Industries Inc.) was interposed between the encapsulation film on the back sheet and the encapsulation film on the front sheet, and then heated and laminated in a vacuum lamination device to complete an encapsulated module structure. Afterward, the short-circuit current and the maximum output power of the encapsulated solar cell were measured to calculate the short-circuit current gain and the maximum output power gain of the module structure, as shown in Table 9.

Four (2×2) series-connected solar cells (Motech Industries Inc.) were interposed between the encapsulation film on the back sheet and the encapsulation film on the front sheet, and then heated and laminated in a vacuum lamination device to complete an encapsulated module structure. The potential induced degradation (PID) of the encapsulated solar cell was measured, as shown in Table 3.

### Comparative Example 5

10 kg of hydrogenated styrene elastomer resin (S1611, commercially available from Asahi Chemical Co. Ltd.), 0.1 kg of polyhedral oligomeric silsesquioxane POSS-AM0265 (commercially available from Hybrid Plastic Inc.), and 0.1 kg of N-hydroxypropyl-1,8-naphthalene diimide were put into a single screw blender FRP-V32C (commercially available from MEISEI KINZOKU MFG. CO. LTD.) to be pelletized to serve as a composition of a light conversion layer. The temperature of the single screw blender was set at 120° C. to 150° C., and the optimal temperature was set as four segments, such as 130° C., 140° C., 140° C., and 130° C. After pelletization, the pellets of the light conversion layer were extruded by an extruder HP-50 (commercially available from GANG LING MACHINERY CO., LTD.) to form a film. The pellets was pre-heated at 150° C. for 10 minutes, and then pressed at 150° C. by a pressure of 100 kg/cm² for 10 minutes to form an encapsulation film with a thickness of 476 micrometers. The transmittance, the viscosity at 150° C., the haze, the breakdown voltage, the volume resistivity, and the encapsulation ability (whether obvious breakage occurred) of the encapsulation film are listed in Table 8.

The encapsulation film was put on a front sheet (super clear glass, commercially available from TAIWAN GLASS IND. CORP.), and the other encapsulation film was put on a back sheet (commercially available from Taiflex scientific CO. LTD.). The commercially available solar cell (Motech Industries Inc.) was interposed between the encapsulation film on the back sheet and the encapsulation film on the front sheet, and then heated and laminated in a vacuum lamination device to complete an encapsulated module structure. Afterward, the short-circuit current and the maximum output power of the encapsulated solar cell were measured to calculate the short-circuit current gain and the maximum output power gain of the module structure, as shown in Table 9.

Four (2×2) series-connected solar cells (Motech Industries Inc.) were interposed between the encapsulation film on the back sheet and the encapsulation film on the front sheet, and then heated and laminated in a vacuum lamination device to complete an encapsulated module structure. The potential induced degradation (PID) of the encapsulated solar cell was measured, as shown in Table 3.

TABLE 8

| | Comparative | Comparative | Comparative | Comparative | Comparative |
|---|---|---|---|---|---|
| | Example 1 | Example 2 | Example 3 | Example 4 | Example 5 |
| Resin | EVA | Hydrogenated | Hydrogenated | Hydrogenated | Hydrogenated |
| | | styrene | styrene | styrene | styrene |
| | | elastomer | elastomer | elastomer | elastomer |
| Additive (%) | None | None | POSS265 (1%) | Blend with | Blend with |
| | | | | POSS265 (0.25%) | POSS265 (1%) |
| | | | | and N-hydroxypropyl- | and N-hydroxypropyl- |
| | | | | 1,8-naphthalene | 1,8-naphthalene |
| | | | | diimide (0.25%) | diimide (1%) |
| Transmittance | 97.85% | 96.87% | 96.91% | 96.04% | 88.45% |
| Viscosity | Not | 4643 | 7196 | 1512 | 1629 |
| @150° C. | measured | | | | |
| (Pa · S) | | | | | |
| Haze | 0.65 | 2.84 | 8.98 | 2.08 | 39.64 |
| Thickness | 402 μm | 623 μm | 497 μm | 683 μm | 476 μm |
| Breakdown | 17.6 | 20.8 | 18.5 | 20.5 | 19 |
| voltage (KV) | | | | | |
| Breakdown | 43.8 | 33.4 | 37.2 | 30.0 | 39.9 |
| voltage (KV)/ | | | | | |
| Thickness (mm) | | | | | |
| Volume | 1.04E14 | 1.09E16 | 1.07E16 | 9.92E16 | 2.15E16 |
| resistivity | | | | | |
| (Ω · cm) | | | | | |
| Encapsulation | Ordinary | Ordinary | Ordinary | Ordinary | Ordinary |
| ability | | | | | |

In Table 8, the thickness, the transmittance, the rheological viscosity, the haze, the breakdown voltage, and the volume resistivity were measured by tools and standards similar to those in Table 1.

TABLE 9

| | Comparative | Comparative | Comparative | Comparative | Comparative |
|---|---|---|---|---|---|
| | Example 1 | Example 2 | Example 3 | Example 4 | Example 5 |
| Resin | EVA | Hydrogenated | Hydrogenated | Hydrogenated | Hydrogenated |
| | | styrene | styrene | styrene | styrene |
| | | elastomer | elastomer | elastomer | elastomer |
| Additive (%) | None | None | POSS265 (1%) | Blend with | Blend with |
| | | | | POSS265 (0.25%) | POSS265 (1%) |
| | | | | and N-hydroxypropyl- | and N-hydroxypropyl- |
| | | | | 1,8-naphthalene | 1,8-naphthalene |
| | | | | diimide (0.25%) | diimide (1%) |
| Short-circuit | 1.68% | 2.93% | 2.28% | 4.747% | 2.869% |
| current gain (%) | | | | | |
| Maximum | 2.54% | 1.94% | 2.98% | 3.773% | 0.519% |
| output power | | | | | |
| gain (%) | | | | | |

In Table 9, the maximum output power gain and the short-circuit current gain were measured by a standard similar to that in Example 2. As shown in Table 9, the short-circuit current gain and the maximum output power gain of Comparative Examples 1 to 5 were lower than those in Examples 1 to 7 (as shown in Table 2, 5, and 7) Only the encapsulation film containing the POSS265 and the small molecule such as N-hydroxypropyl-1,8-naphthalene diimide in Comparative Example 4 had higher maximum output power gain and higher short-circuit current gain, but its PID was extremely large (e.g. the PID after 288 hours was greater than 30%, see Table 3).

The encapsulation material should simultaneously includes properties such as anti-PID, high flowability, and power generation benefit. According to Examples and Comparative Examples, it is obvious that the advantages can only be achieved by grafting the POSS to the fluorescent molecule. If the POSS and the fluorescent molecule are only blended in the encapsulation film, the POSS and the fluorescent molecule cannot be uniformly dispersed in the resin due to inter-particle aggregation, thereby degrading the optical properties of the encapsulation film. As such, only grafting the POSSto the fluorescent molecule as mentioned in Examples could achieve the advantages of optical gain, anti-PID, increasing flowability, and the like.

It will be apparent to those skilled in the art that various modifications and variations can be made to the disclosed methods and materials. It is intended that the specification and examples be considered as exemplary only, with the true scope of the disclosure being indicated by the following claims and their equivalents.

What is claimed is:

1. An encapsulation material, comprising:
a resin; and
a fluorescent molecule,
wherein the fluorescent molecule includes a fluorescent group bonded to a polyhedral oligomeric silsesquioxane.

2. The encapsulation material as claimed in claim 1, wherein the resin and the fluorescent molecule have a weight ratio of 100:0.1 to 100:5.

3. The encapsulation material as claimed in claim 1, wherein the fluorescent molecule has a chemical structure of: 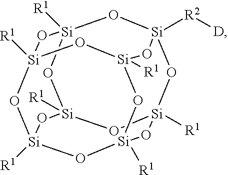
wherein R¹ is linear or branched C₃₋₁₀ alkyl group,
wherein R² is —(CₘH₂ₘ)—, —(CₘH₂ₘ—O—CₓH₂ₓ)—, —(CₘH₂ₘ—NR³—CₓH₂ₓ)—, —(CₘH₂ₘ-Ph-CₙH₂ₙ—O—CₓH₂ₓ)—, —(CₘH₂ₘ-Ph-CₙH₂ₙ—NR³—CₓH₂ₓ)—, —(CₘH₂ₘ—Cy-CₙH₂ₙ—O—CₓH₂ₓ)—, or —(CₘH₂ₘ-Cy-CₙH₂ₙ—NR³—CₓH₂ₓ)—, m=1-5, n=1-5, x=1-5, Cy is cyclohexyl group, and R³ is linear or branched C₁₋₅ alkyl group or hydrogen; and
D is

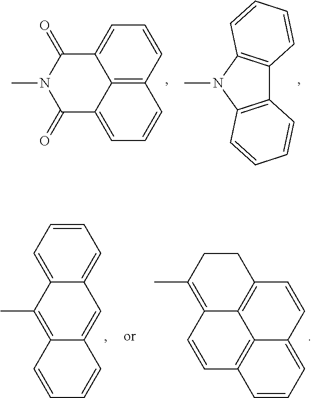

4. The encapsulation material as claimed in claim 1, wherein the resin comprises hydrogenated styrene elastomer resin, acrylate elastomer resin, or ethylene vinyl acetate copolymer.

5. The encapsulation material as claimed in claim 4, wherein the hydrogenated styrene elastomer resin comprises hydrogenated poly(styrene-b-isoprene), hydrogenated poly(styrene-b-isoprene-b-styrene), hydrogenated poly(styrene-b-butadiene-b-styrene), hydrogenated poly(styrene-b-isoprene/butadiene-b-styrene, hydrogenated poly(styrene-b-vinyl bonded rich polyisoprene), or a combination thereof.

6. The encapsulation material as claimed in claim 4, wherein the acrylate elastomer resin comprises poly(methyl methacrylate-b-isoprene), poly(methyl methacrylate-butadiene), poly(methyl methacrylate-b-isoprene-b-methyl methacrylate), poly(methyl methacrylate-b-butadiene-b-methyl methacrylate), poly(methyl methacrylate-b-isoprene/butadiene-b-methyl methacrylate), poly(methyl methacrylate-b-vinyl bonded rich polyisoprene), or a combination thereof.

7. A module structure, comprising:
a front sheet;
a back sheet opposite to the front sheet; and
a solar cell disposed between the front sheet and the back sheet,
wherein a first encapsulation film is disposed between the solar cell and the front sheet; and
a second encapsulation film is disposed between the solar cell and the back sheet,
wherein the first encapsulation film and the second encapsulation film include an encapsulation material, including:
a resin; and
a fluorescent molecule,
wherein the fluorescent molecule includes a fluorescent group bonded to a polyhedral oligomeric silsesquioxane.

8. The module structure as claimed in claim 7, wherein the fluorescent molecule has a chemical structure of: 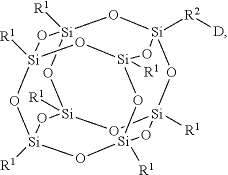
wherein R¹ is linear or branched C₃₋₁₀ alkyl group,
wherein R² is —(CₘH₂ₘ)—, —(CₘH₂ₘ—O—CₓH₂ₓ)—, —(CₘH₂ₘ—NR³—CₓH₂ₓ)—, —(CₘH₂ₘ-Ph-CₙH₂ₙ—O—CₓH₂ₓ)—, —(CₘH₂ₘ-Ph-CₙH₂ₙ—NR³—CₓH₂ₓ)—, —(CₘH₂ₘ—Cy-CₙH₂ₙ—O—CₓH₂ₓ)—, or —(CₘH₂ₘ-Cy-CₙH₂ₙ—NR³—CₓH₂ₓ)—, m=1-5, n=1-5, x=1-5, Cy is cyclohexyl group, and R³ is linear or branched C₁₋₅ alkyl group or hydrogen; and
D is

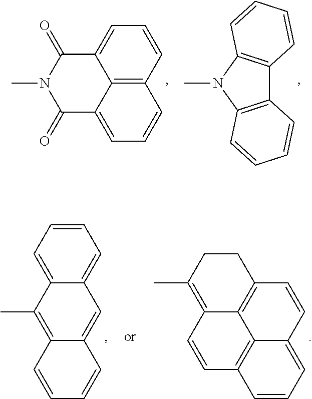

9. The module structure as claimed in claim 7, wherein the resin comprises hydrogenated styrene elastomer resin, acrylate elastomer resin, or ethylene vinyl acetate copolymer.

10. The module structure as claimed in claim 7, wherein each of the front sheet and the back sheet independently includes polyolefin or glass.

11. The module structure as claimed in claim 7, wherein the solar cell includes bifacial solar cell.

12. The module structure as claimed in claim 7, wherein each of the first encapsulation film and the second encapsulation film independently has a thickness of 200 micrometers to 1000 micrometers.
